(19) United States
(12) Patent Application Publication
(10) Pub. No.: US 2015/0061700 A1
(43) Pub. Date: Mar. 5, 2015

(54) CAPACITIVE SENSOR

(71) Applicant: J TOUCH Corporation, Taoyuan County (TW)

(72) Inventors: Yu-Chou YEH, Taoyuan County (TW); Ting-Ching LIN, Taoyuan County (TW); Kun-Ming CHANG, Taoyuan County (TW); Yi-Chin CHEN, Taoyuan County (TW); Yung-Chuan HSU, Taoyuan County (TW)

(73) Assignee: J TOUCH Corporation, Taoyuan County (TW)

(21) Appl. No.: 14/133,141

(22) Filed: Dec. 18, 2013

(30) Foreign Application Priority Data
Aug. 27, 2013 (TW) 102216012

(51) Int. Cl. G01R 27/26

(52) U.S. Cl. CPC G01R 27/2605
USPC 324/658

(57) ABSTRACT

A capacitive sensor applies to a capacitive touch panel and includes a plurality of first electrodes, a plurality of second electrodes, and a plurality of virtual electrodes. The first electrodes each have a first wire portion. The second electrodes are disposed beneath and insulated from the first electrodes, and cross the first electrodes. The second electrodes each have a second wire portion. The virtual electrodes are each disposed between and spaced from two corresponding ones of the first electrodes. The virtual electrodes each include a plurality of continuous portions and a plurality of interrupted portions. The interrupted portions each overlap a corresponding one of the second wire portions of the second electrodes. The width of each of the interrupted portions is less than or equal to the width of the corresponding second wire portion.

The current application claims a foreign priority to the patent application of Taiwan No. 102216012 filed on Aug. 27, 2013.

### FIELD OF THE INVENTION

The present invention relates to capacitive sensors for use with capacitive touch panels, and more particularly, to a capacitive sensor comprising electrodes made from fine metallic wires.

### BACKGROUND OF THE INVENTION

A conventional touch panel is characterized in that virtual electrodes are formed between sensing electrodes arranged in a row and electrically insulated rather than electrically connected with the sensing electrodes to thereby reduce parasitic capacitance between the sensing electrodes and preclude a short circuit between two adjacent ones of the sensing electrodes driven at high frequency.

The virtual electrodes must have plenty of interrupted portions which are totally different from the continuous (uninterrupted) wire pattern of the sensing electrodes. When light rays from a backlight source pass through the virtual electrodes and the sensing electrodes, the light rays are hidden by the virtual electrodes and the sensing electrodes to different degrees, thereby resulting in uneven brightness of the display frame watched by naked eyes.

In view of the shortcomings of the conventional touch panel, the inventor of the present invention conducted extensive researches and experiments and finally developed a capacitive sensor to overcome the aforesaid shortcomings.

### SUMMARY OF THE INVENTION

It is an objective of the present invention to provide a capacitive sensor conducive to enhancement of uniformity of brightness of the display frame of a capacitive touch panel.

In order to achieve the above and other objectives, the present invention provides a capacitive sensor, applicable to a capacitive touch panel, comprising: a plurality of first electrodes each having a first wire portion; a plurality of second electrodes disposed beneath the first electrodes, insulated from the first electrodes, and crossing the first electrodes, the second electrodes each having a second wire portion; and a plurality of virtual electrodes each disposed between two adjacent ones of the first electrodes to space apart the two adjacent ones of the first electrodes, the virtual electrodes each comprising a plurality of continuous portions and a plurality of interrupted portions, wherein the interrupted portions each overlap a corresponding one of the second wire portions of the second electrodes, and a width of each of the interrupted portions is less than or equal to a width of the corresponding second wire portion.

### BRIEF DESCRIPTION OF THE DRAWINGS

Technical features and advantages of the present invention are hereunder illustrated with preferred embodiments in conjunction with the accompanying drawings, in which:

FIG. 1 is a schematic view of the structure of a capacitive sensor according to the present invention;

FIG. 2 is a schematic view of the structure of second electrodes and virtual electrodes of the capacitive sensor according to the present invention; and

FIG. 3 is a partial enlarged view of FIG. 2.

### DETAILED DESCRIPTION OF THE EMBODIMENTS

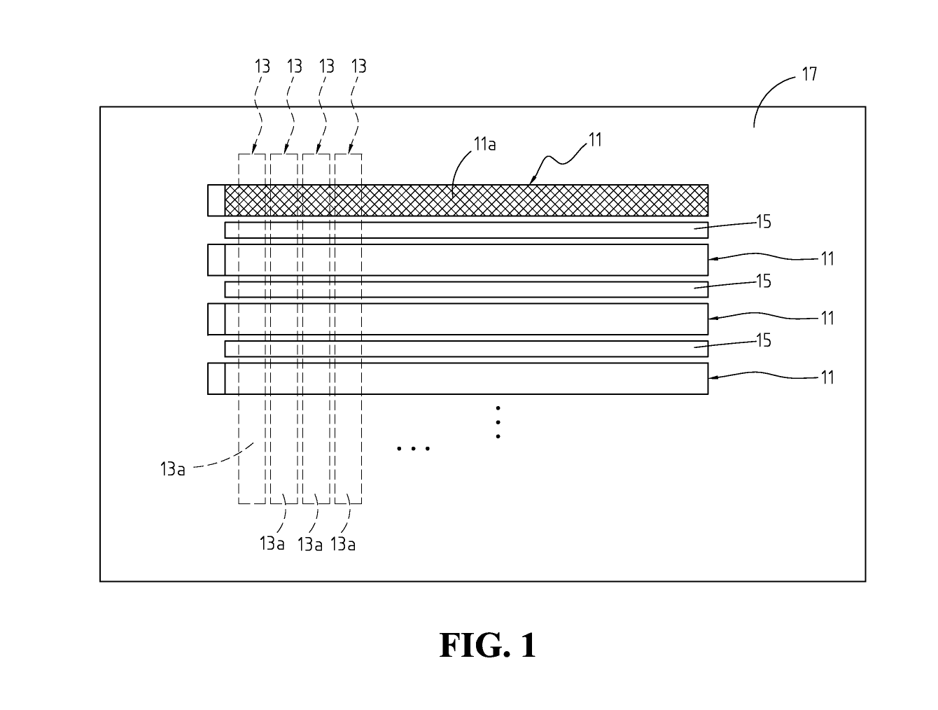

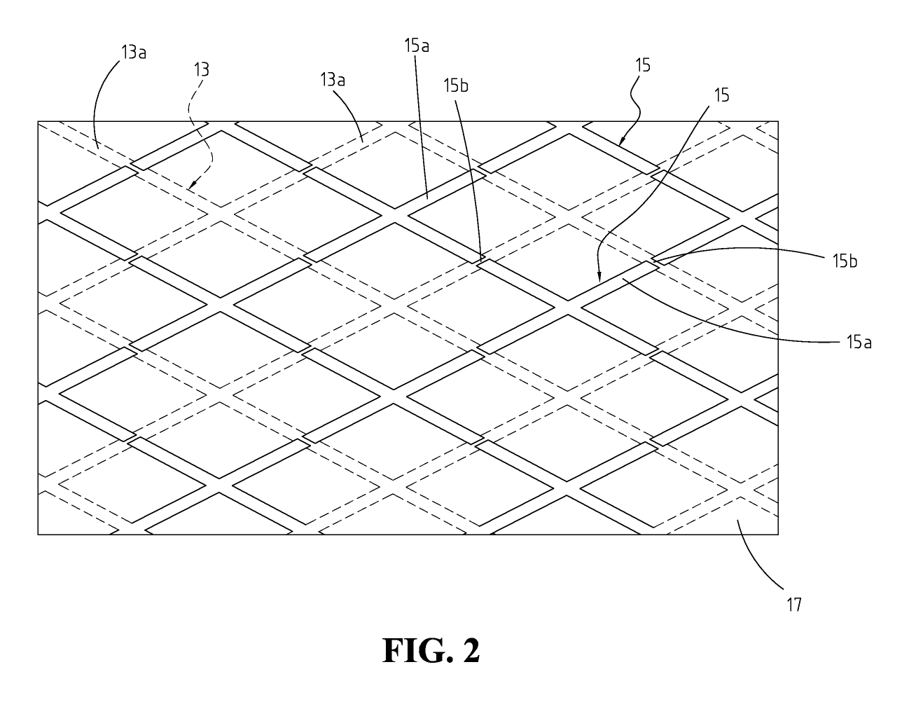

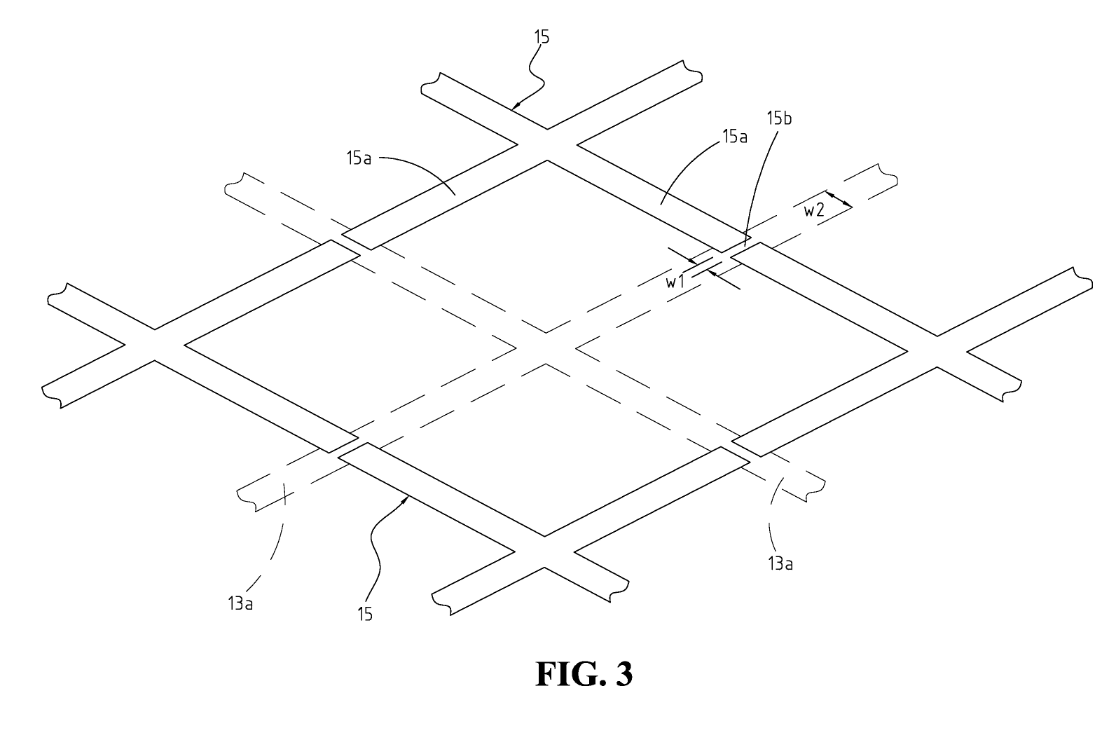

Referring to FIG. 1 through FIG. 3, a capacitive sensor 10 of the present invention is for use with a capacitive touch panel. The capacitive sensor 10 comprises a plurality of first electrodes 11, a plurality of second electrodes 13, and a plurality of virtual electrodes 15, which are described below. The first electrodes 11, the second electrodes 13, and the virtual electrodes 15 are disposed at a transparent substrate 17. For example, the first electrodes 11 and the virtual electrodes 15 are formed on the upper surface of the transparent substrate 17, whereas the second electrodes 13 are formed on the lower surface of the transparent substrate 17. With the transparent substrate 17 being made of an electrically insulating material, not only are the first electrodes 11 insulated from the second electrodes 13, but the virtual electrodes 15 are also insulated from the second electrodes 13.

In an embodiment of the present invention, the first electrodes 11 each have a first wire portion 11a. The first wire portions 11a come in the form of reticular electrically conductive fine metallic wires. The second electrodes 13 are each disposed beneath the first electrodes 11 and insulated therefrom. The second electrodes 13 each have a second wire portion 13a. In an embodiment, the second wire portions 13a come in the form of reticular electrically conductive fine metallic wires. The first electrodes 11 each run in a first direction of the transparent substrate 17. The second electrodes 13 each run in a second direction of the transparent substrate 17. The first direction and the second direction are not parallel. Hence, the first electrodes 11 are each insulated from the second electrodes 13 and cross the second electrodes 13. For example, the first direction and the second direction are perpendicular to each other, and thus the first electrodes 11 are each insulated from the second electrodes 13 and perpendicular thereto. Both the first wire portions 11a and the second wire portions 13a are reticular electrically conductive fine metallic wires.

The reticular electrically conductive fine metallic wires of the first wire portions 11a and the second wire portions 13a are made of copper, aluminum, nickel, iron, gold, silver, stainless steel, tungsten, chromium, titanium, or an alloy thereof. The linear shape of the reticular electrically conductive fine metallic wires is straight or arcuate.

The virtual electrodes 15 are each disposed between two adjacent ones of the first electrodes 11 to space apart the two adjacent ones of the first electrodes 11. The virtual electrodes 15 each comprise a plurality of continuous portions 15a and a plurality of interrupted portions 15b. In an embodiment, the continuous portions 15a are two electrically conductive fine metallic wires which cross each other and thus are cruciform or X-shaped. The two electrically conductive fine metallic wires which cross each other are made of copper, aluminum, nickel, iron, gold, silver, stainless steel, tungsten, chromium, titanium, or an alloy thereof. The linear shape of the two electrically conductive fine metallic wires which cross each other is linear or arcuate.

The interrupted portions 15b each overlap a corresponding one of the second wire portions 13a of the second electrodes 13. The width W1 of each of the interrupted portions 15b is less than or equal to the width W2 of the corresponding second wire portion 13a. With each said interrupted portion 15b being hidden by the corresponding second wire portion 13a below, the light rays from the backlight source of the capacitive touch panel are blocked by the second wire portion 13a and thus cannot pass through each of the interrupted portions 15b, thereby enhancing the uniformity of brightness of the display frame of the capacitive touch panel.

Both the vertically adjacent ones of the continuous portions 15a and the horizontally adjacent ones of the continuous portions 15a are separated by the interrupted portions 15b and spaced apart by a predetermined distance. The interrupted portions 15b can be directly formed from the transparent substrate 17, such that none of the continuous portions 15a is connected to two vertically adjacent ones of the continuous portions 15a and two horizontally adjacent ones of the continuous portions 15a.

The capacitive sensor 10 of the present invention is advantageously characterized in that: the virtual electrodes 15 are improved in a manner that the interrupted portions 15b are each hidden by the second wire portion 13a of the second electrodes 13 below to thereby enhance the uniformity of brightness of the display frame of the capacitive touch panel.

The present invention is disclosed above by preferred embodiments. However, persons skilled in the art should understand that the preferred embodiments are illustrative of the present invention only, but should not be interpreted as restrictive of the scope of the present invention. Hence, all equivalent changes and modifications made in accordance with the claims and the specification of the present invention to the aforesaid embodiments should fall within the scope of the present invention.

What is claimed is:

1. A capacitive sensor, applicable to a capacitive touch panel, comprising:
a plurality of first electrodes each having a first wire portion;
a plurality of second electrodes disposed beneath the first electrodes, insulated from the first electrodes, and crossing the first electrodes, the second electrodes each having a second wire portion; and
a plurality of virtual electrodes each disposed between two adjacent ones of the first electrodes to space apart the two adjacent ones of the first electrodes, the virtual electrodes each comprising a plurality of continuous portions and a plurality of interrupted portions, wherein the interrupted portions each overlap a corresponding one of the second wire portions of the second electrodes, and a width of each of the interrupted portions is less than or equal to a width of the corresponding second wire portion.

2. The capacitive sensor of claim 1, wherein the first wire portions are reticular electrically conductive fine metallic wires.

3. The capacitive sensor of claim 1, wherein the second wire portions are reticular electrically conductive fine metallic wires.

4. The capacitive sensor of claim 1, wherein the continuous portions are electrically conductive fine metallic wires, and every two of which cross each other.

5. The capacitive sensor of claim 1, further comprising a transparent substrate on which the first electrodes, the second electrodes, and the virtual electrodes are disposed.

6. The capacitive sensor of any one of claims 1, wherein the electrically conductive fine metallic wires are made of one selected from the group consisting of copper, aluminum, nickel, iron, gold, silver, stainless steel, tungsten, chromium, titanium, and an alloy thereof.

7. The capacitive sensor of any one of claims 2, wherein the electrically conductive fine metallic wires are made of one selected from the group consisting of copper, aluminum, nickel, iron, gold, silver, stainless steel, tungsten, chromium, titanium, and an alloy thereof.

8. The capacitive sensor of any one of claims 3, wherein the electrically conductive fine metallic wires are made of one selected from the group consisting of copper, aluminum, nickel, iron, gold, silver, stainless steel, tungsten, chromium, titanium, and an alloy thereof.
